(19) United States
(12) Patent Application Publication
(10) Pub. No.: US 2026/0188606 A1
(43) Pub. Date: Jul. 2, 2026

(54) ASTIGMATISM CORRECTION METHOD OF ELECTRON BEAM IMAGING DEVICE, PRODUCT AND APPARATUS

(71) Applicant: Dongfang Jingyuan Electron Co., LTD, Beijing (CN)

(72) Inventors: Caihong YANG, Beijing (CN); Chunying Han, Beijing (CN); Feng Ning, Beijing (CN); Xiwen Jia, Beijing (CN); Chengcheng Liu, Beijing (CN)

(21) Appl. No.: 19/419,554

(22) Filed: Dec. 15, 2025

(30) Foreign Application Priority Data
Dec. 26, 2024 (CN) 202411943595.4

(51) Int. Cl. H01J 37/153; G01N 23/2251; H01J 37/28

(52) U.S. Cl. CPC H01J 37/153; G01N 23/2251; G01N 2223/401; H01J 37/28; H01J 2237/1532

(57) ABSTRACT

Provided are an astigmatism correction method of an electron beam imaging device, a product and an apparatus. The astigmatism correction method includes: searching a target astigmatism parameter of a stigmator in the electron beam imaging device; gradually adjusting a preadjustment objective lens current according to a set step size, and collecting a plurality of fine focused images corresponding to different objective lens currents; calculating gradients of the plurality of fine focused images in different coordinate axis directions; judging whether the target astigmatism parameter meets an astigmatism correction requirement according to consistency of the gradients; and if yes, determining a target objective lens current of the electron beam imaging device according to the gradients. Astigmatism correction accuracy is improved, and the problem that measurement accuracy is low due to application of an error astigmatism correction result is avoided, thereby improving the measurement accuracy of the electron beam imaging device.

### CROSS-REFERENCE TO RELATED APPLICATIONS

The present application claims priority to Chinese patent application No. 202411943595.4 entitled “Astigmatism Correction Method of Electron Beam Imaging Device, Product and Apparatus”, filed on Dec. 26, 2024, the entire contents of which are incorporated herein by reference.

### TECHNICAL FIELD

The present disclosure relates to the field of semiconductor manufacturing and detection, and particularly to an astigmatism correction method of an electron beam imaging device, a product and an apparatus.

### BACKGROUND

In integrated circuit manufacturing, a charged particle beam imaging device enables charged particles to act on a sample by controlling a focusing state of the charged particles, and can represent information of the sample, such as an appearance, a structure and components, by capturing particle signals, such as secondary particles and transmitted particles, for imaging. In the semiconductor field, the charged particle beam imaging device includes a detection device for detecting defects on a surface of a wafer, and an electron beam measurement device for detecting critical dimensions of the wafer.

As a charged particle beam imaging device, a scanning electron microscope (SEM) is configured for defect detection and critical dimension measurement in the fields of semiconductor manufacturing and other micro-nano processing. The device scans a surface of a sample through a high-energy electron beam, and collects and analyzes signals, such as secondary electrons and backscattered electrons, generated by an interaction of electrons and the sample, thereby realizing accurate measurement of a surface appearance and dimensions of the sample. As a high-accuracy imaging device, the SEM needs to ensure stability of imaging quality. In actual measurement, optimal hardware parameters of a state of the SEM may drift to some extent with time, and therefore, some hardware parameters need to be calibrated periodically. Astigmatism calibration is an important calibration item, and automation thereof is particularly important. Manual calibration needs to occupy and consume a certain labor cost, and therefore, an astigmatism correction process needs to be automatically operated. In automatic astigmatism correction and calibration, an orientation and a size of a stigmator are automatically adjusted by analyzing astigmatism features of an image, thereby eliminating astigmatism in the image. The automatic processing not only improves the imaging quality, but also lightens a burden of an operator, reduces requirements on experience of the operator, greatly reduces the labor cost and a time cost, and indirectly improves a measuring efficiency of the SEM.

A solution for performing astigmatism correction adjustment on an image (i.e., SEM image) acquired by the SEM in the prior art includes: selecting an isotropic sample position for astigmatism adjustment, and judging whether astigmatism of a current device needs to be calibrated by calculating frequency spectrum information of a sample pattern and utilizing roundness and area features of a frequency spectrum binary image. However, this solution has certain limitations on the selection of the sample, has relatively high requirements on the experience of the operator, needs the actual operator to understand image features more thoroughly, and has the problems of poor application scene diversity, a high labor cost, or the like. In addition, in this solution, the roundness and area features of the frequency spectrum binary image are used to judge whether the astigmatism of the device needs to be calibrated, and therefore, the solution has high requirements on imaging quality of the SEM image and accuracy of a frequency spectrum image binarization result, and has the problems of relatively poor algorithm noise resistance, a low redundancy search caused by abnormal judgment, a low algorithm running efficiency, low accuracy of an astigmatism correction result, or the like.

In addition, another solution for performing astigmatism correction adjustment on the SEM image in the prior art includes: adjusting an imaging lens of the SEM to be at a focusing distance according to a defocusing degree of the image, and when the imaging lens is at the focusing distance, compositely describing a definition of a focused image by using two quantities (a variance of local variances and a mean of the local variances), and finishing the adjustment of an astigmatism value by using the definition of the focused image as a judgment reference. However, in this solution, after the adjustment of the astigmatism value is completed, completion of the whole automatic astigmatism correction adjustment is directly confirmed, and therefore, this solution cannot avoid application of an error result, and has the problems that algorithm accuracy is low, and normal measurement of the device cannot be guaranteed.

### SUMMARY

In view of the above problems, the present disclosure proposes an astigmatism correction method of an electron beam imaging device, a product and an apparatus, which overcome or at least partially solve the above problems.

An object of the present disclosure is to provide an astigmatism correction method of an electron beam imaging device to ensure astigmatism correction accuracy.

A further object of the present disclosure is to improve accuracy of judging whether astigmatism correction requirements are met, so as to further improve the astigmatism correction accuracy.

A further object of the present disclosure is to improve an astigmatism correction efficiency.

In particular, the present disclosure provides an astigmatism correction method of an electron beam imaging device, including:
searching a target astigmatism parameter of a stigmator in the electron beam imaging device;
gradually adjusting a preadjustment objective lens current according to a set step size, and collecting a plurality of fine focused images corresponding to different objective lens currents;
calculating gradients of the plurality of fine focused images in different coordinate axis directions;
judging whether the target astigmatism parameter meets an astigmatism correction requirement according to consistency of the gradients; and
if yes, determining a target objective lens current of the electron beam imaging device according to the gradients.

Optionally, the step of judging whether the target astigmatism parameter meets an astigmatism correction requirement according to consistency of the gradients includes:
calculating an X-axis gradient score change curve and a Y-axis gradient score change curve of the plurality of fine focused images according to the gradients;
judging whether a symmetric axis of the X-axis gradient score change curve is consistent with a symmetric axis of the Y-axis gradient score change curve;
if yes, confirming that the target astigmatism parameter meets the astigmatism correction requirement; and
if no, confirming that the target astigmatism parameter does not meet the astigmatism correction requirement.

Optionally, the step of determining a target objective lens current of the electron beam imaging device according to the gradients includes:
taking a value of the objective lens current corresponding to the symmetric axis as the target objective lens current.

Optionally, the step of searching a target astigmatism parameter of a stigmator in the electron beam imaging device includes:
gradually adjusting the astigmatism parameter according to an initial astigmatism step size to obtain a plurality of astigmatism comparison images;
searching an adjustment and optimization astigmatism parameter according to variances of the plurality of astigmatism comparison images, the adjustment and optimization astigmatism parameter being taken as an iteration search basis;
iteratively searching the adjustment and optimization astigmatism parameter, reducing the astigmatism step size during each iteration, and stopping the iteration when the astigmatism step size is smaller than preset search stop accuracy; and
taking the adjustment and optimization astigmatism parameter obtained in a last iteration search as the target astigmatism parameter of the stigmator.

Optionally, the step of searching an adjustment and optimization astigmatism parameter according to variances of the plurality of astigmatism comparison images includes:
calculating the variance of each astigmatism comparison image as a definition score of each astigmatism comparison image; and
comparing the definition scores of the plurality of astigmatism comparison images, and taking an astigmatism parameter value corresponding to the astigmatism comparison image with the highest definition score as the adjustment and optimization astigmatism parameter.

Optionally, before the step of searching a target astigmatism parameter of a stigmator in the electron beam imaging device, the astigmatism correction method further includes:
searching the preadjustment objective lens current of the electron beam imaging device; and
setting an objective lens current of the electron beam imaging device to the preadjustment objective lens current.

Optionally, the step of searching the preadjustment objective lens current of the electron beam imaging device includes:
gradually adjusting an initial objective lens current according to a preadjustment current step size, and collecting a plurality of coarse focused images corresponding to different objective lens currents;
calculating definitions of the plurality of coarse focused images; and
searching an adjustment and optimization objective lens current according to the definitions of the plurality of coarse focused images, and taking the searched adjustment and optimization objective lens current as the preadjustment objective lens current.

Optionally, after the step of judging whether the target astigmatism parameter meets an astigmatism correction requirement according to consistency of the gradients, the astigmatism correction method further includes:
outputting an astigmatism calibration failure prompt under the condition that the astigmatism correction requirement is not met.

In another aspect, the present disclosure further provides a computer program product including a computer program which, when being executed by a processor, implements the steps of the astigmatism correction method of an electron beam imaging device in any one of the above descriptions.

In yet another aspect, the present disclosure further provides a computer apparatus including a memory, a processor and a computer program stored in the memory and run on the processor, wherein the processor, when executing the computer program, implements the steps of the astigmatism correction method of an electron beam imaging device in any one of the above descriptions.

In the astigmatism correction method of an electron beam imaging device according to the present disclosure, after the target astigmatism parameter of the stigmator in the electron beam imaging device is searched, the preadjustment objective lens current is adjusted gradually according to the set step size, the plurality of fine focused images corresponding to different objective lens currents are collected, the gradients of the plurality of fine focused images in different coordinate axis directions are calculated, whether the target astigmatism parameter meets the astigmatism correction requirement or not is judged according to the consistency of the gradients, and judgment of an astigmatism correction effect is realized. Therefore, the astigmatism correction method according to the present disclosure can effectively avoid application of an error result, avoid the problems of lower accuracy and incapability of ensuring normal measurement of the device caused by the error astigmatism correction result, and improve the astigmatism correction accuracy, so as to improve measurement accuracy of the electron beam imaging device. In addition, the astigmatism correction method of an electron beam imaging device according to the present disclosure determines the target objective lens current of the electron beam imaging device according to the gradients under the condition that the target astigmatism parameter is confirmed to meet the astigmatism correction requirement. Secondary adjustment of the objective lens current of the electron beam imaging device is realized, and a fine degree of adjustment of the objective lens current is improved, thereby further improving the astigmatism correction accuracy.

Further, in the astigmatism correction method of an electron beam imaging device according to the present disclosure, whether the target astigmatism parameter meets the astigmatism correction requirement is judged by calculating the X-axis gradient score change curve and the Y-axis gradient score change curve of the plurality of fine focused images according to the gradients and judging whether the symmetric axis of the X-axis gradient score change curve is consistent with the symmetric axis of the Y-axis gradient score change curve, such that a judgment standard is optimized, and the accuracy of judging whether the astigmatism correction requirement is met is improved, thereby further improving the astigmatism correction accuracy.

Still further, in the astigmatism correction method of an electron beam imaging device according to the present disclosure, the plurality of astigmatism comparison images are obtained by gradually adjusting the astigmatism parameter according to the initial astigmatism step size, the adjustment and optimization astigmatism parameter is searched according to the variances of the plurality of astigmatism comparison images and used as the iteration search basis, the adjustment and optimization astigmatism parameter is iteratively searched, the astigmatism step size is reduced during each iteration, the iteration is stopped when the astigmatism step size is smaller than the preset search stop accuracy, and the adjustment and optimization astigmatism parameter obtained in the last iteration search is taken as the target astigmatism parameter of the stigmator, thereby realizing searching of the target astigmatism parameter by adopting an inverted pyramid search mode. Therefore, in the astigmatism correction method of an electron beam imaging device according to the present disclosure, the target astigmatism parameter is searched in the inverted pyramid search mode, thus accelerating a searching speed of the target astigmatism parameter of the stigmator, reducing time complexity and space complexity of the search, improving the astigmatism correction efficiency, and meanwhile ensuring stability of the astigmatism correction process.

According to the following detailed description of specific embodiments of the present disclosure in conjunction with drawings, those skilled in the art will better understand the aforementioned and other objects, advantages and features of the present invention.

### BRIEF DESCRIPTION OF THE DRAWINGS

Some specific embodiments of the present invention will be described below in detail in an exemplary rather than restrictive manner with reference to the drawings. Identical reference numerals in the drawings represent identical or similar components or parts. Those skilled in the art should understand that these drawings are not necessarily drawn to scale. In the drawings:

FIG. 1 is a schematic diagram of an embodiment of astigmatism correction adjustment in the prior art;

FIG. 2 is a schematic flow diagram of an astigmatism correction method of an electron beam imaging device according to an embodiment of the present invention;

FIG. 3 is a schematic diagram of a fine focused image in the astigmatism correction method of an electron beam imaging device according to an embodiment of the present invention;

FIG. 4 is a schematic diagram of an X-axis gradient score change curve and a Y-axis gradient score change curve of the fine focused image shown in FIG. 3;

FIG. 5 is a schematic diagram of the fine focused image in the astigmatism correction method of an electron beam imaging device according to another embodiment of the present invention;

FIG. 6 is a schematic diagram of the X-axis gradient score change curve and the Y-axis gradient score change curve of the fine focused image shown in FIG. 5;

FIG. 7 is a schematic flow diagram of the astigmatism correction method of an electron beam imaging device according to another embodiment of the present invention;

FIG. 8 is a schematic structural diagram of a computer program product according to an embodiment of the present invention; and

FIG. 9 is a schematic structural diagram of a computer apparatus according to an embodiment of the present invention.

### DETAILED DESCRIPTION OF EMBODIMENTS

Exemplary embodiments of the present invention will be described in more detail below with reference to the accompanying drawings. While exemplary embodiments of the present invention are shown in the drawings, it should be understood that the present invention may be embodied in various forms and should not be limited by the embodiments set forth herein. Rather, these embodiments are provided such that this disclosure will be thoroughly understood, and will fully convey the scope of the invention to those skilled in the art.

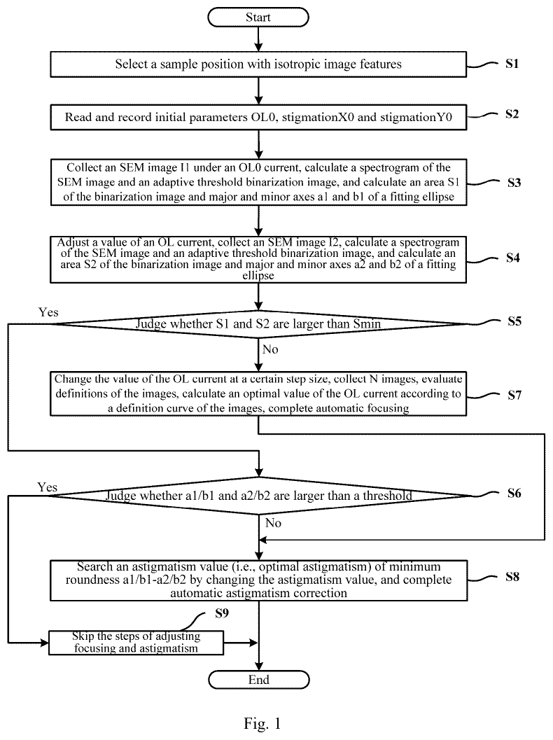

FIG. 1 is a schematic diagram of an embodiment of astigmatism correction adjustment in the prior art. In an existing quality evaluation method, a process of performing astigmatism correction adjustment on an SEM image may include the following steps: step one: selecting a sample position with isotropy; step two: reading and recording a value of a current objective lens (OL) current and a numerical value of an astigmatism parameter; step three: collecting an SEM image I1 under the current OL current, calculating a spectrogram of the SEM image and an adaptive threshold binarization image, and calculating an area S1 of the binarization image and major and minor axes a1 and b1 of a fitting ellipse; step four: adjusting the value of the OL current, collecting an SEM image I2, calculating a spectrogram of the SEM image and an adaptive threshold binarization image, and calculating an area S2 of the binarization image and major and minor axes a2 and b2 of a fitting ellipse; step five: judging whether focusing and astigmatism need to be adjusted according to the areas S1 and S2 and roundness a1/b1 and a2/b2, and proceeding to step seven when S1 and S2 are larger than Smin; otherwise, proceeding to step six; step six: when the roundness is greater than a threshold, avoiding adjustment of the astigmatism parameter, and when the roundness is less than the threshold, adjusting the astigmatism parameter, and proceeding to step eight; step seven: changing the value of the OL current at a certain step size, collecting N images, evaluating definitions of the images, calculating an optimal focal plane according to a definition curve of the images, completing automatic focusing, and proceeding to the step eight; step eight: searching an astigmatism value (i.e., optimal astigmatism) of minimum roundness a1/b1-a2/b2 by changing the astigmatism value, and completing automatic astigmatism correction.

Flow steps of an astigmatism correction adjustment solution in the prior art are described below with reference to FIG. 1.
Step S1: selecting a sample position with isotropic image features;
step S2: reading and recording initial parameters OL0, stigmationX0 and stigmationY0; wherein stigmationX0 refers to initial X-direction astigmatism, and stigmationY0 refers to initial Y-direction astigmatism;
step S3: collecting an SEM image I1 under an OL0 current, calculating a spectrogram of the SEM image and an adaptive threshold binarization image, and calculating an area S1 of the binarization image and major and minor axes a1 and b1 of a fitting ellipse;
step S4: adjusting a value of an OL current, collecting an SEM image I2, calculating a spectrogram of the SEM image and an adaptive threshold binarization image, and calculating an area S2 of the binarization image and major and minor axes a2 and b2 of a fitting ellipse;
step S5: judging whether S1 and S2 are larger than Smin, if yes, proceeding to step S6, and if no, proceeding to step S7;
step S6: judging whether a1/b1 and a2/b2 are larger than a threshold, if yes, proceeding to step S9, and if no, proceeding to step S8;
step S7: changing the value of the OL current at a certain step size, collecting N images, evaluating definitions of the images, calculating an optimal value of the OL current according to a definition curve of the images, completing automatic focusing, and proceeding to step S8; and
step S8: searching an astigmatism value (i.e., optimal astigmatism) of minimum roundness a1/b1-a2/b2 by changing the astigmatism value, and completing automatic astigmatism correction. This process is ended.
Step S9: skipping the steps of adjusting focusing and astigmatism. This process is ended.

This method has certain limitations on selection of a sample, has relatively high requirements on experience of an operator, needs an actual operator to understand image features more thoroughly, and has the problems of poor application scene diversity and a high labor cost. In addition, in this solution, the roundness and area features of a frequency spectrum binary image are used to judge whether the astigmatism of the device needs to be calibrated, and therefore, the solution has high requirements on imaging quality of the SEM image and accuracy of a frequency spectrum image binarization result, and has the problems of relatively poor algorithm noise resistance, a low redundancy search caused by abnormal judgment, a low algorithm running efficiency, and low accuracy of an astigmatism correction result.

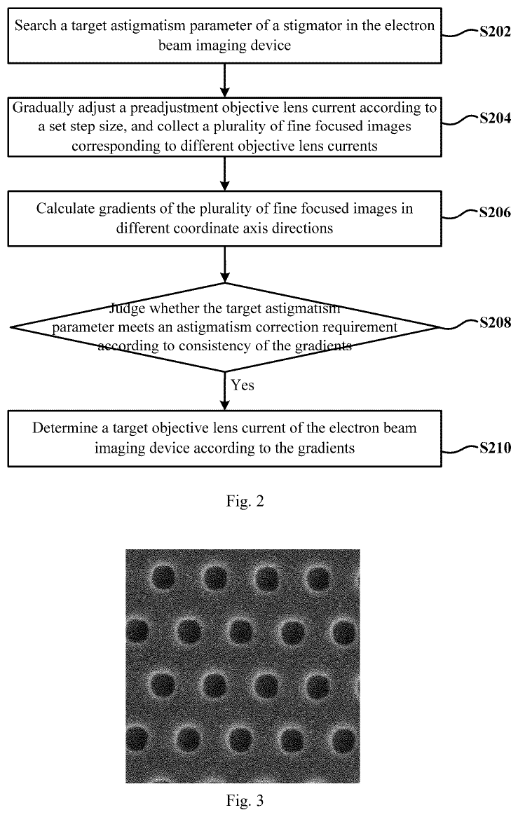

In order to solve the above problems, an embodiment of the present invention provides an astigmatism correction method of an electron beam imaging device. FIG. 2 is a schematic flow diagram of the astigmatism correction method of an electron beam imaging device according to an embodiment of the present invention.

As shown in FIG. 2, the astigmatism correction method of an electron beam imaging device according to an embodiment may generally include:
step S202: searching a target astigmatism parameter of a stigmator in the electron beam imaging device;
step S204: gradually adjusting a preadjustment objective lens current according to a set step size, and collecting a plurality of fine focused images corresponding to different objective lens currents;
step S206: calculating gradients of the plurality of fine focused images in different coordinate axis directions;
step S208: judging whether the target astigmatism parameter meets an astigmatism correction requirement according to consistency of the gradients, and if yes, executing step S210;
step S210: determining a target objective lens current of the electron beam imaging device according to the gradients.

In this embodiment, astigmatism parameters required to be adjusted in the stigmator may include X-direction astigmatism (which may be denoted as StigmationX) and Y-direction astigmatism (which may be denoted as StigmationY). Thus, the target astigmatism parameters of the stigmator include target X-direction astigmatism (which may be denoted as BestStigX) and target Y-direction astigmatism (which may be denoted as BestStigY). Correspondingly, the gradients of the fine focused images in different coordinate axis directions may include X-axis gradients and Y-axis gradients of the fine focused images.

In addition, an objective lens (OL) is a last focusing lens in an SEM, and is responsible for focusing an electron beam of the electron beam imaging device to a quite small spot, so as to form a high-resolution image on a sample. Adjusting the objective lens current (which may be denoted as OL current) can change magnetic field strength of the objective lens, thereby changing a focusing state of the electron beam and then affecting magnification of the SEM image. In addition, the preadjustment objective lens current (which may be denoted as OL_opt) may be a value of the objective lens current which is searched in a previous coarse focusing step and may initially improve imaging quality.

In the astigmatism correction method of an electron beam imaging device according to the present invention, after the target astigmatism parameter of the stigmator in the electron beam imaging device is searched, the preadjustment objective lens current is adjusted gradually according to the set step size, the plurality of fine focused images corresponding to different objective lens currents are collected, the gradients of the plurality of fine focused images in different coordinate axis directions are calculated, whether the target astigmatism parameter meets the astigmatism correction requirement or not is judged according to the consistency of the gradients, and judgment of an astigmatism correction effect is realized. Therefore, the astigmatism correction method according to the present invention can effectively improve correctness of the astigmatism correction result, and improve the astigmatism correction accuracy, thereby improving measurement accuracy of the electron beam imaging device.

In addition, the astigmatism correction method of an electron beam imaging device according to the present invention determines the target objective lens current of the electron beam imaging device according to the gradients under the condition that the target astigmatism parameter is confirmed to meet the astigmatism correction requirement, such that secondary adjustment of the objective lens current of the electron beam imaging device is realized, and a fine degree of adjustment of the objective lens current is improved, thereby further improving the astigmatism correction accuracy.

In some embodiments, after the step S210, the astigmatism correction method of an electron beam imaging device according to the present invention may further include the following step: outputting an astigmatism calibration failure prompt under the condition that the astigmatism correction requirement is not met. That is, when the target astigmatism parameter does not meet the astigmatism correction requirement, the astigmatism calibration failure prompt is output, and the process is ended.

Therefore, the astigmatism correction method according to the present invention can effectively avoid application of an error result, avoid the problems of lower accuracy and incapability of ensuring normal measurement of the device caused by the error astigmatism correction result, and thus further improve the astigmatism correction accuracy, so as to improve the measurement accuracy of the electron beam imaging device.

In some embodiments, before the step S202, the astigmatism correction method of an electron beam imaging device according to the present invention may further include the following steps: searching the preadjustment objective lens current of the electron beam imaging device; and setting an objective lens current of the electron beam imaging device to the preadjustment objective lens current. That is, in the astigmatism correction method according to the present invention, the preadjustment objective lens current of the electron beam imaging device is first searched, and then, the searched preadjustment objective lens current is taken as the objective lens current of the electron beam imaging device, and on this basis, the target astigmatism parameter of the stigmator in the electron beam imaging device is searched.

Further, the step of searching the preadjustment objective lens current of the electron beam imaging device may include the following steps: gradually adjusting an initial objective lens current according to a preadjustment current step size, and collecting a plurality of coarse focused images corresponding to different objective lens currents; calculating definitions of the plurality of coarse focused images; and searching an adjustment and optimization objective lens current according to the definitions of the plurality of coarse focused images, and taking the searched adjustment and optimization objective lens current as the preadjustment objective lens current. It should be noted that the definitions of the plurality of coarse focused images may include definition curve gradients of the plurality of coarse focused images. In addition, the searched preadjustment objective lens current is used in the subsequent process of searching the target astigmatism parameter of the stigmator in the electron beam imaging device. That is, the astigmatism correction method of an electron beam imaging device according to the present invention can roughly determine a position of an image focal plane by roughly adjusting the objective lens current (OL current).

In a specific embodiment, the step of searching the preadjustment objective lens current of the electron beam imaging device may be specifically performed as the following steps: continuously adjusting the value of the OL current, and collecting a plurality of images; dynamically adjusting a search step size according to the definition curve gradients of the plurality of coarse focused images, and quickly searching to a relatively clear focal plane position to realize coarse focusing; and recording a preferred objective lens current OL_opt as the searched preadjustment objective lens current. It should be noted that the relatively clear degree may be determined according to a value of a dynamic step size, and the larger the value is, the lower the accuracy is, and the lower the relatively clear degree is. Therefore, if the preadjustment current step size is reduced subsequently to perform an accurate search in a small range, the relatively clear degree of the coarse focused images can be improved. In an optional implementation of the above embodiment, a stop condition for the quickly searching to the relatively clear focal plane position may be set to the condition that a definition curve of the coarse focused image exhibits a quadratic parabola with a downward opening. In another optional implementation, the stop condition for the quickly searching to the relatively clear focal plane position may also be set to the condition that a search number exceeds a preset maximum search number.

Thus, in the astigmatism correction method of an electron beam imaging device according to the present invention, by firstly performing coarse focusing and then performing astigmatism correction calibration, the imaging quality is obviously improved, a basic definition and resolution of the image are ensured, and an efficiency and accuracy of the subsequent operation of searching the target astigmatism parameter are improved.

In some embodiments, the step S202 may include the following steps: gradually adjusting the astigmatism parameter according to an initial astigmatism step size to obtain a plurality of astigmatism comparison images; searching an adjustment and optimization astigmatism parameter according to variances of the plurality of astigmatism comparison images, the adjustment and optimization astigmatism parameter being taken as an iteration search basis; iteratively searching the adjustment and optimization astigmatism parameter, reducing the astigmatism step size during each iteration, and stopping the iteration when the astigmatism step size is smaller than preset search stop accuracy; and taking the adjustment and optimization astigmatism parameter obtained in the last iteration search as the target astigmatism parameter of the stigmator. Therefore, the astigmatism correction method of an electron beam imaging device according to the present invention realizes the search of the target astigmatism parameter by adopting an inverted pyramid search mode. It should be noted that specific steps of the inverted pyramid search mode may include: 1: searching with an initial step size within a certain range to determine an optimal value B1; 2: searching near B1 with a reduced step size to determine an optimal value B2; and 3: repeating the operations until the step size meets minimum set accuracy. The inverted pyramid search mode can shorten a search time.

Therefore, in the astigmatism correction method of an electron beam imaging device according to the present invention, the target astigmatism parameter is searched in the inverted pyramid search mode, thereby increasing a searching speed of the target astigmatism parameter of the stigmator, reducing time complexity and space complexity of the search, improving the astigmatism correction efficiency, and meanwhile ensuring stability of the astigmatism correction process.

In some embodiments, the variance of the astigmatism comparison image may reflect a degree of dispersion of gray values of the astigmatism comparison image, and may be used for evaluation of the definition of the astigmatism comparison image. Specifically, the larger the variance of the image, the larger the gray difference in the image, that is, the clearer the image. Therefore, in a specific embodiment, the step of searching an adjustment and optimization astigmatism parameter according to variances of the plurality of astigmatism comparison images may include the following steps: calculating the variance of each astigmatism comparison image as a definition score of each astigmatism comparison image; and comparing the definition scores of the plurality of astigmatism comparison images, and taking an astigmatism parameter value corresponding to the astigmatism comparison image with the highest definition score as the adjustment and optimization astigmatism parameter. In another specific embodiment, the step of searching an adjustment and optimization astigmatism parameter according to variances of the plurality of astigmatism comparison images may be further specifically performed as follows: taking an astigmatism parameter value corresponding to the astigmatism comparison image with the largest variance as the adjustment and optimization astigmatism parameter.

Therefore, in the astigmatism correction method of an electron beam imaging device according to the present invention, the definition of the astigmatism comparison image is evaluated by calculating the variance of the astigmatism comparison image, an image scoring standard is optimized, and astigmatism correction accuracy is improved.

In some embodiments, the step S202 may include searching BestStigX and BestStigY of the stigmator in the electron beam imaging device using the inverted pyramid search mode.

In a specific embodiment, the step of searching BestStigX of the stigmator in the electron beam imaging device using the inverted pyramid search mode may be specifically performed as the following steps: acquiring preset search stop accuracy (which can be denoted as StigStopAcuuracy) and a search range (which can be denoted as StigRange); adjusting StigmationX in StigRange with a certain step size, taking the variance of the image as an image score, obtaining a best score in searching of each layer, performing searching of the next layer again at a best score astigmatism position, repeating the operations, stopping iterations when a current pyramid search step size is smaller than StigStopAcuuracy, and recording an X-direction astigmatism value corresponding to the best score of the current layer as BestStigX.

In addition, the step of searching BestStigY of the stigmator in the electron beam imaging device using the inverted pyramid search mode may be specifically performed as the following steps: acquiring preset search stop accuracy (which can be denoted as StigStopAcuuracy) and a search range (which can be denoted as StigRange); adjusting StigmationY in StigRange with a certain step size, taking the variance of the image as an image score, obtaining a best score in searching of each layer, performing searching of the next layer again at a best score astigmatism position, repeating the operations, stopping iterations when a current pyramid search step size is smaller than StigStopAcuuracy, and recording a Y-direction astigmatism value corresponding to the best score of the current layer as BestStigY.

Therefore, in the astigmatism correction method of an electron beam imaging device according to the present invention, the target X-direction astigmatism and the target Y-direction astigmatism are respectively searched in the inverted pyramid search mode, and searching accuracy of the target X-direction astigmatism and the target Y-direction astigmatism is ensured while the searching speed of the target astigmatism parameter of the stigmator is increased, thereby further ensuring the stability of the astigmatism correction process.

In some embodiments, the step S204 may be specifically executed as the following steps: with OL_opt as a center, gradually adjusting the value of the OL current according to the set step size, and collecting the plurality of fine focused images corresponding to different values of the OL current. It should be noted that the set step size may be preset according to parameters, such as an OL focal length of the electron beam imaging device. In a specific embodiment, the set step size may be set such that a change quantity of the OL focal length is 1 to 10 microns after the value of the OL current is adjusted with the set step size. Therefore, the astigmatism correction method of an electron beam imaging device according to the present invention can realize fine adjustment of the OL focal length, thereby improving image collection accuracy and efficiency.

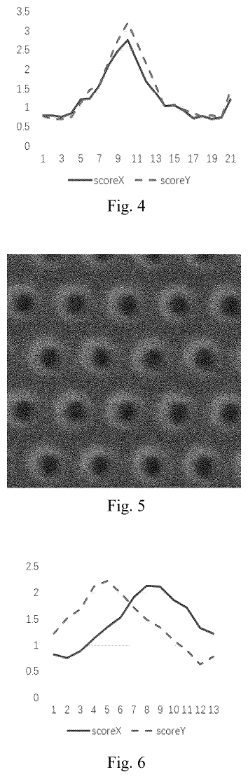

FIG. 3 is a schematic diagram of the fine focused image in the astigmatism correction method of an electron beam imaging device according to an embodiment of the present invention, which shows one fine focused image in the case where the target astigmatism parameter meets the astigmatism correction requirement. FIG. 4 is a schematic diagram of the X-axis gradient score change curve and the Y-axis gradient score change curve of the fine focused image shown in FIG. 3, which shows shapes and positions of the symmetric axes of the X-axis gradient score change curve and the Y-axis gradient score change curve of the fine focused image in the case where the target astigmatism parameter meets the astigmatism correction requirement. FIG. 5 is a schematic diagram of the fine focused image in the astigmatism correction method of an electron beam imaging device according to another embodiment of the present invention, which shows one fine focused image in the case where the target astigmatism parameter does not meet the astigmatism correction requirement. FIG. 6 is a schematic diagram of the X-axis gradient score change curve and the Y-axis gradient score change curve of the fine focused image shown in FIG. 5, which shows shapes and positions of the symmetric axes of the X-axis gradient score change curve and the Y-axis gradient score change curve of the fine focused image in the case where the target astigmatism parameter does not meet the astigmatism correction requirement.

As shown in FIG. 3 to FIG. 6, in some embodiments, the step S206 may include the following step: calculating X-axis gradients and Y-axis gradients of the plurality of fine focused images. Further, the step S208 may include the following steps: calculating an X-axis gradient score change curve and a Y-axis gradient score change curve of the plurality of fine focused images according to the gradients; judging whether a symmetric axis of the X-axis gradient score change curve is consistent with a symmetric axis of the Y-axis gradient score change curve; if yes, confirming that the target astigmatism parameter meets the astigmatism correction requirement; and if no, confirming that the target astigmatism parameter does not meet the astigmatism correction requirement. Therefore, the astigmatism correction method of an electron beam imaging device according to the present invention establishes a guarantee mechanism for astigmatism correction calibration, thereby avoiding calibration failure caused by abnormal conditions, such as jitter or image frame loss.

It should be noted that the astigmatism correction requirement may indicate that both the X-direction astigmatism and the Y-direction astigmatism are successfully eliminated or reduced to be within a preset range. It is confirmed that the target astigmatism parameter meets the astigmatism correction requirement under the condition that both the X-direction astigmatism and the Y-direction astigmatism are successfully eliminated or reduced to be within the preset range.

In addition, a gradient score is an index for measuring a change speed of an image in a certain direction. In an imaging system of the electron beam imaging device, the gradient score may reflect a definition and a contrast of an image edge. When the gradient score of the image in a certain direction is higher, the image edge in the direction is clear and high in contrast, and otherwise, the image edge is fuzzy and low in contrast. Therefore, under the condition that the X-direction astigmatism and the Y-direction astigmatism are successfully eliminated or reduced to be within the preset range, the electron beam can be focused to one spot after passing through the imaging system, and a clear image is formed. At this point, the gradient scores of the image in the X-axis and Y-axis directions should be substantially uniform regardless of the change in the objective lens current (or working distance).

Therefore, as shown in FIG. 4, the symmetric axis of the X-axis gradient score change curve is consistent with the symmetric axis of the Y-axis gradient score change curve of the fine focused image, which indicates that the gradient scores of the fine focused image in the X-axis direction and the Y-axis direction have consistency at optimal positions under different working distances (WDs), such that it can be determined that both the X-direction astigmatism and the Y-direction astigmatism are successfully eliminated or reduced to be within the preset range, and it is further confirmed that the target astigmatism parameter meets the astigmatism correction requirement. At this point, as shown in FIG. 3, in the case where the target astigmatism parameter meets the astigmatism correction requirement, the fine focused image is clear.

In addition, as shown in FIG. 6, the symmetric axis of the X-axis gradient score change curve is inconsistent with the symmetric axis of the Y-axis gradient score change curve of the fine focused image, which indicates that the gradient scores of the fine focused image in the X-axis direction and the Y-axis direction do not have consistency at the optimal positions under different working distances (WDs), such that it can be determined that at least one of the X-direction astigmatism and the Y-direction astigmatism is not successfully eliminated, and it is further confirmed that the target astigmatism parameter does not meet the astigmatism correction requirement. At this point, as shown in FIG. 5, in the case where the target astigmatism parameter does not meet the astigmatism correction requirement, the fine focused image is fuzzy.

Thus, in the astigmatism correction method of an electron beam imaging device according to the present invention, whether the target astigmatism parameter meets the astigmatism correction requirement is judged by calculating the X-axis gradient score change curve and the Y-axis gradient score change curve of the plurality of fine focused images according to the gradients and judging whether the symmetric axis of the X-axis gradient score change curve is consistent with the symmetric axis of the Y-axis gradient score change curve, such that a judgment standard is optimized, and the accuracy of judging whether the astigmatism correction requirement is met is improved, thereby further improving the astigmatism correction accuracy.

In some embodiments, the step of determining a target objective lens current of the electron beam imaging device according to the gradients may include the following step: taking the value of the objective lens current corresponding to the symmetric axis as the target objective lens current (which may be denoted as BestOL). That is, in the case where the symmetric axis of the X-axis gradient score change curve is consistent with the symmetric axis of the Y-axis gradient score change curve, that is, in the case where the astigmatism calibration succeeds, the value of the OL current corresponding to the symmetric axis is taken as BestOL, thereby realizing fine focusing.

Therefore, in the astigmatism correction method of an electron beam imaging device according to the present invention, by taking the value of the objective lens current corresponding to the symmetric axis as the target objective lens current after the astigmatism calibration is successful, fine focusing is realized, thereby further improving the imaging quality and further improving the astigmatism correction effect.

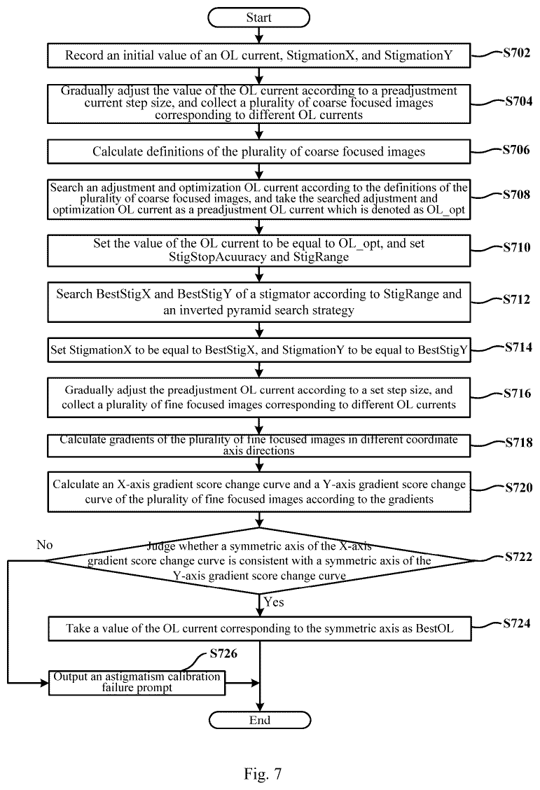

FIG. 7 is a schematic flow diagram of the astigmatism correction method of an electron beam imaging device according to another embodiment of the present invention. Flow steps of this embodiment are specifically described below with reference to FIG. 7.
Step S702: recording an initial value of an OL current, StigmationX, and StigmationY.
Step S704: gradually adjusting the value of the OL current according to a preadjustment current step size, and collecting a plurality of coarse focused images corresponding to different OL currents.
Step S706: calculating definitions of the plurality of coarse focused images.
Step S708: searching an adjustment and optimization OL current according to the definitions of the plurality of coarse focused images, and taking the searched adjustment and optimization OL current as OL_opt. It should be noted that, through this step, the search can rapidly reach a relatively clear focal plane position, and a coarse focusing process is completed.
Step S710: setting the value of the OL current to be equal to OL_opt, and setting StigStopAcuuracy and StigRange.
Step S712: searching BestStigX and BestStigY of a stigmator according to StigRange and an inverted pyramid search strategy.
Step S714: setting StigmationX to be equal to BestStigX, and StigmationY to be equal to BestStigY.
Step S716: gradually adjusting a preadjustment OL current according to a set step size, and collecting a plurality of fine focused images corresponding to different OL currents.
Step S718: calculating gradients of the plurality of fine focused images in different coordinate axis directions.
Step S720: calculating an X-axis gradient score change curve and a Y-axis gradient score change curve of the plurality of fine focused images according to the gradients.
Step S722: judging whether a symmetric axis of the X-axis gradient score change curve is consistent with a symmetric axis of the Y-axis gradient score change curve, if yes, executing step S724, and if no, executing step S726.
Step S724: taking a value of the OL current corresponding to the symmetric axis as BestOL. At this point, a fine focusing process is completed, and the process of astigmatism correction is ended.
Step S726: outputting an astigmatism calibration failure prompt. At this point, a process of judgment of the astigmatism correction effect is completed, and the process of astigmatism correction is ended.

It should be noted that the above steps S702 to S726 describe one astigmatism correction process of the astigmatism correction method of an electron beam imaging device according to the present invention. If an astigmatism correction command is received again in the following period, the process can be restarted in response to the astigmatism correction command.

Therefore, by adding the step of judgment of the astigmatism correction effect after the target astigmatism parameter of the stigmator in the electron beam imaging device is searched, the astigmatism correction method of an electron beam imaging device according to the present invention can effectively avoid the application of the error result, avoid the problems of lower accuracy and incapability of ensuring normal measurement of the device caused by the error astigmatism correction result, and improve the astigmatism correction accuracy, so as to improve the measurement accuracy of the electron beam imaging device. In addition, the astigmatism correction method of an electron beam imaging device according to the present invention also determines the target objective lens current of the electron beam imaging device according to the gradients under the condition that the target astigmatism parameter is confirmed to meet the astigmatism correction requirement, such that secondary adjustment of the objective lens current of the electron beam imaging device is realized, and the fine degree of adjustment of the objective lens current is improved, thereby further improving the astigmatism correction accuracy.

Further, in the astigmatism correction method of an electron beam imaging device according to the present invention, whether the target astigmatism parameter meets the astigmatism correction requirement is judged by calculating the X-axis gradient score change curve and the Y-axis gradient score change curve of the plurality of fine focused images according to the gradients and judging whether the symmetric axis of the X-axis gradient score change curve is consistent with the symmetric axis of the Y-axis gradient score change curve, such that the judgment standard is optimized, and the accuracy of judging whether the astigmatism correction requirement is met is improved, thereby further improving the astigmatism correction accuracy.

Still further, in the astigmatism correction method of an electron beam imaging device according to the present invention, the target astigmatism parameter is searched in the inverted pyramid search mode, thus accelerating the searching speed of the target astigmatism parameter of the stigmator, reducing time complexity and space complexity of the search, improving the astigmatism correction efficiency, and meanwhile ensuring the stability of the astigmatism correction process.

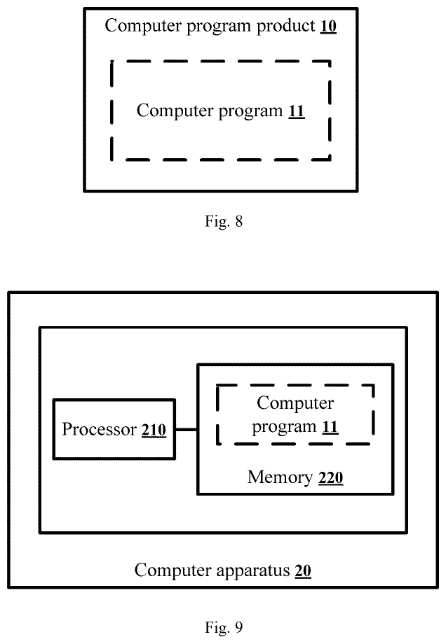

The present disclosure further provides a computer program product and a computer apparatus. FIG. 8 is a schematic structural diagram of the computer program product 10 according to an embodiment of the present invention, and FIG. 9 is a schematic structural diagram of the computer apparatus 20 according to an embodiment of the present invention.

The computer program product 10 has a computer program 11 stored therein, the computer program 11 implementing the astigmatism correction method of an electron beam imaging device according to any one of the embodiments described above when executed by a processor.

The computer apparatus 20 may include a memory 220, a processor 210 and a computer program 11 which is stored in the memory 220 and run on the processor 210, wherein the processor 210 implements the astigmatism correction method of an electron beam imaging device according to any one of the embodiments described above when executing the computer program 11.

It should be noted that the logic and/or steps described in the flow charts or in other manners, e.g., a sequential list of executable instructions for implementing logic functions, may be implemented in any computer program product for usage of instruction execution systems, apparatuses or devices, such as computer-based systems, systems including processors, or other systems which can read instructions from an instruction execution system, apparatus or device and execute them, or in combination with the instruction execution systems, apparatuses or devices to use.

In the description of this embodiment, the computer program product 10 may be any apparatus that contains, stores, communicates, propagates or transmits programs for an instruction execution system, apparatus or device or in combination therewith for the usage. More specific examples (a non-exhaustive list) of the computer program product 10 include the following elements: an electrical connection portion (electronic apparatus) having one or more wires, a portable computer diskette (magnetic apparatus), a random access memory (RAM), a read-only memory (ROM), an erasable programmable read-only memory (EPROM or flash memory), an optical fiber apparatus, and a portable compact disc read-only memory (CDROM). Further, the computer program product 10 may even be paper or another suitable medium upon which the program is printed, because the program can be electronically obtained by for instance performing optical scanning on the paper or other medium, and then editing, interpreting or otherwise processing an obtained content if necessary, and then, the program is stored in a computer memory.

It should be understood that each element described in the present disclosure may be implemented with hardware, software, firmware or a combination thereof. In the above implementation, a plurality of steps or methods may be implemented in software or firmware which is stored in the memory and executed by a suitable instruction execution system.

The computer apparatus 20 may be, for example, a server, a desktop computer, a notebook computer, a tablet computer, or a smartphone. In some examples, the computer apparatus 20 may be a cloud computing node. The computer apparatus 20 may be described in the general context of computer system-executable instructions (such as program modules) executed by a computer system. Generally, the program modules may include routines, programs, object programs, components, logic, data structures, or the like, that perform particular tasks or implement particular abstract data types. The computer apparatus 20 may be implemented in a distributed cloud computing environment where tasks are performed by remote processing devices that are linked through a communication network. In the distributed cloud computing environment, the program modules may be located in storage media of a local or remote computing system including storage devices.

The computer apparatus 20 may include a processor 210 adapted to execute stored instructions, and a memory 220 that provides a temporary storage space for operations of the instructions during operations. The processor 210 may be a single-core processor, a multi-core processor, a computing cluster, or any number of other configurations. The memory 220 may include a random access memory (RAM), a read only memory, a flash memory, or any other suitable storage systems.

The flow charts provided in the embodiments are not intended to indicate that the operations of the method are to be performed in any particular order, or that all of the operations of the method are to be included in each case. Further, the method may include additional operations. Additional variations on the above-described method are possible within the scope of the technical idea provided by the method according to the embodiments.

So far, those skilled in the art should be aware that, although plural exemplary embodiments of the present invention have been shown and described herein in detail, a lot of other variations or modifications conforming to the principle of the present invention can still be directly determined or derived from the contents disclosed in the present invention without departing from the spirit and scope of the present invention. Therefore, the scope of the present invention should be understood and deemed as covering all of these other variations or modifications.

What is claimed is:

1. An astigmatism correction method of an electron beam imaging device, comprising:
searching a target astigmatism parameter of a stigmator in the electron beam imaging device;
gradually adjusting a preadjustment objective lens current according to a set step size, and collecting a plurality of fine focused images corresponding to different objective lens currents;
calculating gradients of the plurality of fine focused images in different coordinate axis directions;
judging whether the target astigmatism parameter meets an astigmatism correction requirement according to consistency of the gradients; and
if yes, determining a target objective lens current of the electron beam imaging device according to the gradients.

2. The astigmatism correction method of the electron beam imaging device according to claim 1,
wherein the step of judging whether the target astigmatism parameter meets an astigmatism correction requirement according to consistency of the gradients comprises:
calculating an X-axis gradient score change curve and a Y-axis gradient score change curve of the plurality of fine focused images according to the gradients;
judging whether a symmetric axis of the X-axis gradient score change curve is consistent with a symmetric axis of the Y-axis gradient score change curve;
if yes, confirming that the target astigmatism parameter meets the astigmatism correction requirement; and
if no, confirming that the target astigmatism parameter does not meet the astigmatism correction requirement.

3. The astigmatism correction method of the electron beam imaging device according to claim 2,
wherein the step of determining a target objective lens current of the electron beam imaging device according to the gradients comprises:
taking a value of the objective lens current corresponding to the symmetric axis as the target objective lens current.

4. The astigmatism correction method of the electron beam imaging device according to claim 1,
wherein the step of searching a target astigmatism parameter of a stigmator in the electron beam imaging device comprises:
gradually adjusting the astigmatism parameter according to an initial astigmatism step size to obtain a plurality of astigmatism comparison images;
searching an adjustment and optimization astigmatism parameter according to variances of the plurality of astigmatism comparison images, the adjustment and optimization astigmatism parameter being taken as an iteration search basis;
iteratively searching the adjustment and optimization astigmatism parameter, reducing the astigmatism step size during each iteration, and stopping the iteration when the astigmatism step size is smaller than preset search stop accuracy; and
taking the adjustment and optimization astigmatism parameter obtained in a last iteration search as the target astigmatism parameter of the stigmator.

5. The astigmatism correction method of the electron beam imaging device according to claim 4,
wherein the step of searching an adjustment and optimization astigmatism parameter according to variances of the plurality of astigmatism comparison images comprises:
calculating the variance of each astigmatism comparison image as a definition score of each astigmatism comparison image; and
comparing the definition scores of the plurality of astigmatism comparison images, and taking an astigmatism parameter value corresponding to the astigmatism comparison image with the highest definition score as the adjustment and optimization astigmatism parameter.

6. The astigmatism correction method of the electron beam imaging device according to claim 1,
wherein before the step of searching a target astigmatism parameter of a stigmator in the electron beam imaging device, the astigmatism correction method further comprises:
searching the preadjustment objective lens current of the electron beam imaging device; and
setting an objective lens current of the electron beam imaging device to the preadjustment objective lens current.

7. The astigmatism correction method of the electron beam imaging device according to claim 6,
wherein the step of searching the preadjustment objective lens current of the electron beam imaging device comprises:
gradually adjusting an initial objective lens current according to a preadjustment current step size, and collecting a plurality of coarse focused images corresponding to different objective lens currents;
calculating definitions of the plurality of coarse focused images; and
searching an adjustment and optimization objective lens current according to the definitions of the plurality of coarse focused images, and taking the searched adjustment and optimization objective lens current as the preadjustment objective lens current.

8. The astigmatism correction method of the electron beam imaging device according to claim 1,
wherein after the step of judging whether the target astigmatism parameter meets an astigmatism correction requirement according to consistency of the gradients, the astigmatism correction method further comprises:
outputting an astigmatism calibration failure prompt under the condition that the astigmatism correction requirement is not met.

9. A computer program product comprising a computer program which, when being executed by a processor, implements the steps of the astigmatism correction method of an electron beam imaging device according to claim 1.

10. A computer apparatus comprising a memory, a processor and a computer program stored in the memory and run on the processor, wherein the processor, when executing the computer program, implements the steps of the astigmatism correction method of an electron beam imaging device according to claim 1.
